(19) United States
(12) Patent Application Publication
(10) Pub. No.: US 2009/0243079 A1
(43) Pub. Date: Oct. 1, 2009

(54) Semiconductor device package

(76) Inventors: Seung-won Lim, Bucheon-si (KR); O-seob Jeon, Seoul (KR); Seung-yong Choi, Seoul (KR); Joon-seo Son, Seoul (KR); Man-kyo Jong, Bucheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 12/381,957

(22) Filed: Mar. 17, 2009

(30) Foreign Application Priority Data
Mar. 31, 2008 (KR) 10-2008-0029917

(51) Int. Cl. H01L 23/48; H01L 21/50

(52) U.S. Cl. 257/691; 438/121; 257/778; 257/737; 257/E23.01; 257/E21.499

(57) ABSTRACT

Provided is a semiconductor device package including a substrate formed of a silicon (Si)-based material. The semiconductor device package includes a first substrate which comprises first and second principal planes which are opposite each other, and a substrate body layer disposed between the first and second principal planes, the substrate body layer being formed of a silicon (Si)-based material; and at least one first semiconductor device which is mounted on the first principal plane.

### CROSS-REFERENCES TO RELATED APPLICATIONS

This application claims the benefit of Korean Patent Application No. 10-2008-0029917, filed on Mar. 31, 2008, in the Korean Intellectual Property Office, the disclosure of which is incorporated herein in its entirety by reference.

### BACKGROUND OF THE INVENTION

1. Field of the Invention

Embodiments of the present invention relate to a semiconductor device package, and more particularly, to a semiconductor device package including a substrate formed of a silicon (Si)-based material.

2. Description of the Related Art

Conventionally, a printed circuit board (PCB), a ceramic substrate, a direct bonded copper (DBC) substrate, or an insulated metal substrate (IMS) is used as a substrate for mounting a semiconductor device. If the semiconductor device is a power device, the substrate needs to provide an interconnection pattern for the power device or to dissipate heat generated from the power device. Compared to a substrate used in a low-power circuit device such as a logic circuit, a power device substrate needs to have a high dielectric breakdown strength and durability against a repetitive heat cycle during the operation of a circuit device.

Although the ceramic substrate, the DBC substrate, and the IMS of the above-mentioned substrates have an excellent thermal resistance, the interconnection pattern may not be easily formed on these substrates and materials of themselves are relatively expensive. Also, because these substrates have different thermal expansion coefficients from that of the semiconductor chips to be mounted thereon, life spans of those substrates may be reduced due to a repetitive heat cycle. In the case of the IMS, an epoxy-based dielectric layer having a low thermal conductivity is employed between a metal base plate and a copper (Cu) interconnection pattern and thus heat dissipation efficiency is low.

Furthermore, in a conventional semiconductor device package, because semiconductor devices are electrically connected to each other by a wire bonding process, if the size of the semiconductor device package is reduced, sufficient distances between the wires cannot be ensured and thus errors due to shorts may frequently occur. As described above, in order to manufacture a small and light semiconductor device package, the above-described problem of the wire bonding process has to be solved.

Embodiments of the invention address these and other problems individually and collectively.

### SUMMARY OF THE INVENTION

Embodiments of the present invention provide for a semiconductor device package, including a substrate which has excellent heat dissipation and heat resistance, and is manufactured at a relatively low cost. Embodiments of the invention are also directed to methods for making such semiconductor device packages.

Embodiments of the present invention also provide for a small and light semiconductor device package which minimizes the need for, or is a substitute for, a wire bonding process.

According to an aspect of the present invention, there is provided a semiconductor device package comprising: a first substrate which comprises first and second principal planes which are opposite each other, and a substrate body layer disposed between the first and second principal planes, the substrate body layer being formed of a silicon (Si)-based material; and at least one first semiconductor device which is mounted on the first principal plane. The first substrate may be a base substrate which is attached on the second principal plane of the first substrate, and at least a portion of the second principal plane of the first substrate may be exposed outside a molding member. Alternatively, the semiconductor device package may further include a base substrate which is mounted on the second principal plane of the first substrate. A lower surface of the base substrate is exposed outside of a molding member.

In some embodiments, the first substrate may further include at least one first conductive pattern which is formed on the first principal plane and is electrically connected to the first semiconductor device. The at least one first conductive pattern may comprise at least one first contact pad. Also, the first conductive pattern may comprise at least one die attach paddle on which the first semiconductor device is mounted. The first substrate may further comprise a redistribution layer for electrically connecting at least two of the first conductive patterns to each other.

At least one of the first contact pads may be electrically connected to an external terminal of the first semiconductor device, by using a conductive connection member. The conductive connection member may be a conductive bump or a solder ball. Alternatively, the first semiconductor device may be bonded on the die attach paddles by using adhesive members, and at least one of the first contact pads may be electrically connected to an external terminal of the first semiconductor device, by performing a wire bonding process.

In some embodiments, the semiconductor device package may further comprise a second semiconductor device which is mounted on the second principal plane of the first substrate. In this case, the first substrate may further comprise a plurality of second conductive patterns which are formed on the second principal plane, and at least one of the second conductive patterns may be electrically connected to the second semiconductor device. At least one of the first conductive patterns and at least one of the second conductive patterns may be electrically connected to each other by a via conductor which pierces through the substrate body layer of the first substrate. The first and second semiconductor devices may be electrically connected to at least one of the first conductive patterns and at least one of the second conductive patterns, respectively, by using conductive connection members.

The first substrate may be formed of at least two substrate body layers which are stacked on one another. At least one of the substrate body layers may include a redistribution layer, and at least another one of the substrate body layers may include a via conductor.

According to another aspect of the present invention, there is provided a semiconductor device package including a first substrate comprising a first principal plane on which a plurality of first conductive patterns are formed, a second principal plane which is opposite the first principal plane, and a substrate body layer disposed between the first and second principal planes, the substrate body layer being formed of a silicon (Si)-based material; a second substrate comprising a first principal plane on which a plurality of second conductive patterns are formed, and a second principal plane which is opposite the first principal plane; and a semiconductor device disposed between the first principal plane of the first substrate and the first principal plane of the second substrate, the semiconductor device being electrically connected to at least one of the first conductive patterns and at least one of the second conductive patterns, by using a plurality of conductive connection members.

The conductive connection members may be conductive bumps or solder balls. Also, the conductive connection members may include a first conductive connection member which has a first height and bonds at least one of the first conductive patterns of the first substrate with an external terminal of the semiconductor device; and a second conductive connection member which has a second height and bonds at least another portion of the first conductive patterns of the first substrate with at least a portion of the second conductive patterns of the second substrate.

The second substrate may be a flexible printed circuit board (FPCB). Alternatively, the second substrate may be a printed circuit board (PCB), an insulated metal substrate (IMS), a pre-molded substrate, or a direct bonded copper (DBC) substrate.

These and other embodiments of the invention are described in further detail in the Detailed Description below with reference to the Figures.

### BRIEF DESCRIPTION OF THE DRAWINGS

The above and other features and advantages of the present invention will become more apparent by describing in detail exemplary embodiments thereof with reference to the attached drawings in which:

FIGS. 1A through 1D are perspective views of substrates formed of a silicon (Si)-based material, according to various embodiments of the present invention;

FIG. 2A is a perspective view of a semiconductor device package according to an embodiment of the present invention;

FIG. 2B is a cross-sectional view of the semiconductor device package which is illustrated in FIG. 2A and is taken along a line II-II, according to an embodiment of the present invention;

FIG. 3A is a perspective view of a semiconductor device package according to another embodiment of the present invention;

FIG. 3B is a cross-sectional view of the semiconductor device package which is illustrated in FIG. 3A and is taken along a line III-III, according to an embodiment of the present invention;

FIG. 4A is a perspective view of a semiconductor device package according to another embodiment of the present invention;

FIG. 4B is a cross-sectional view of the semiconductor device package which is illustrated in FIG. 4A and is taken along a line IV-IV, according to an embodiment of the present invention;

FIGS. 5A through 5C are cross-sectional views of semiconductor device packages in which substrates are encapsulated into a molding member and are used as signal substrates, according to various embodiments of the present invention;

FIG. 6 is a cross-sectional view of a semiconductor device package according to another embodiment of the present invention; and

FIG. 7 is a cross-sectional view of a semiconductor device package according to another embodiment of the present invention.

### DETAILED DESCRIPTION OF THE INVENTION

Embodiments of the present invention will now be described more fully with reference to the accompanying drawings, in which exemplary embodiments of the invention are shown.

Embodiments of the invention may, however, be embodied in many different forms and should not be construed as being limited to the embodiments set forth herein; rather, these embodiments are provided so that this disclosure will be thorough and complete, and will fully convey the concept of the invention to those skilled in the art.

It will also be understood that when a layer is referred to as being “on” another layer or substrate, it can be directly on the other layer or substrate, or intervening layers may also be present. In the drawings, the thicknesses and sizes of layers and regions are exaggerated for clarity, and like reference numerals in the drawings denote like elements. The term “and/or” used herein includes any and all combinations of one or more of the associated listed items.

The terms used herein are for illustrative purpose of the present invention only and should not be construed to limit the meaning or the scope of the present invention. As used in this specification, a singular form may, unless definitely indicating a particular case in terms of the context, include a plural form. Also, the expressions “comprise” and/or “comprising” used in this specification neither define the mentioned shapes, numbers, steps, operation, member, elements, and/or groups of these, nor exclude the presence or addition of one or more other different shapes, numbers, steps, operations, members, elements, and/or groups of these, or addition of these. Also, the term “connect” and the like is not limiting and can include direct and indirect connections though intervening elements.

As used herein, terms such as “first,” “second,” etc., are used to describe various members, components, regions, layers, and/or portions. However, it is obvious that the members, components, regions, layers, and/or portions should not be defined by these terms. The terms are used only for distinguishing one member, component, region, layer, or portion from another member, component, region, layer, or portion. Thus, a first member, component, region, layer, or portion which will be described may also refer to a second member, component, region, layer, or portion, without departing from the scope of the present invention.

In the drawings, modification of the illustrated shapes may be expected according to the manufacturing technique and/or tolerance in the drawings. Accordingly, the embodiments of the present invention should not be construed as being limited to the particular forms in the illustrated drawings, and should include changes in the shape caused during the manufacturing process.

As used herein, a silicon (Si)-based material is a material which includes Si and on which a conventional Si-based semiconductor manufacturing process may be performed. Accordingly, an example of the Si-based material is a Si wafer. The Si-based material is not limited by its crystallinity, conductivity, or defect properties, or by the method by which it is made. Embodiments of the invention are described herein with reference to schematic illustrations of specific embodiments (and intermediate structures). As such, variations from the shapes of the illustrations as a result, for example, of manufacturing techniques and/or tolerances, are to be expected. Thus, the embodiments of the invention should not be construed as limited to the particular shapes of regions illustrated herein, but are to include deviations in shapes that result, for example, from manufacturing. Like reference numerals denote like elements in the drawings.

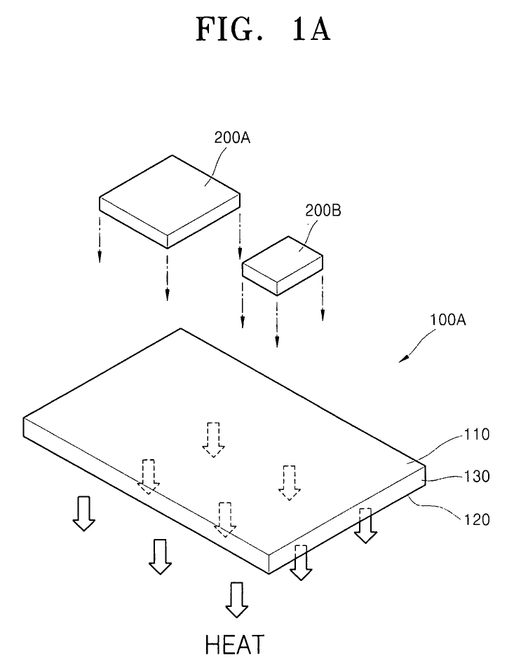

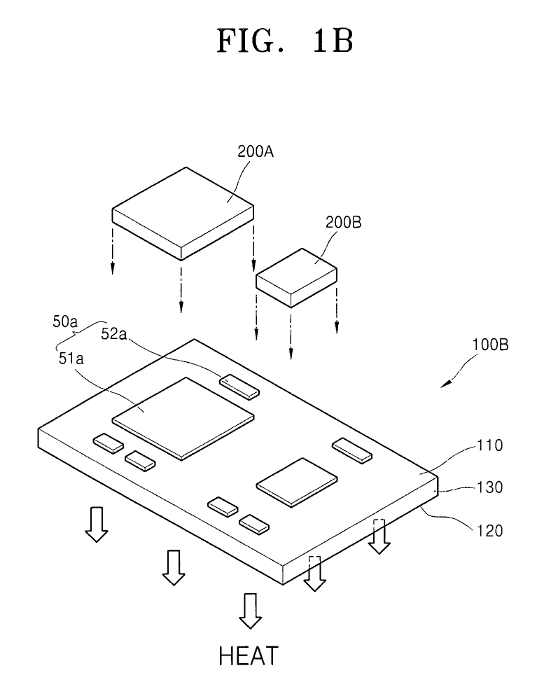

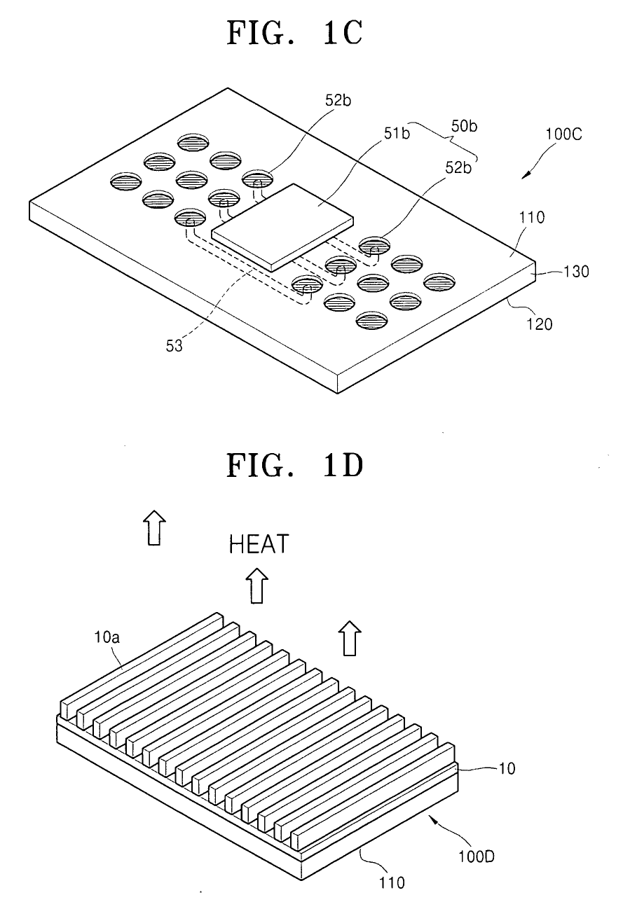

FIGS. 1A through 1D are perspective views of substrates 100A, 100B, 100C, and 100D, respectively, which are formed of a Si-based material, according to various embodiments of the present invention.

Referring to FIGS. 1A through 1D, a semiconductor device package according to an embodiment of the present invention includes at least one of the substrates 100A, 100B, 100C, and 100D, each including first and second principal planes 110 and 120 which are opposite each other, and a substrate body layer 130 which is disposed between the first and second principal planes 110 and 120. The first principal plane 110 may provide an insulation surface on which an appropriate conductive pattern is formed, which will be described in detail later.

If a semiconductor device 200A such as a high power device, and a semiconductor device 200B (e.g., a low power device) for controlling the power device are mounted on the first principal plane 110, then the second principal plane 120 provides a heat dissipation surface for removing the heat generated from the first principal plane 110 in a direction indicated by arrows. The substrate body layer 130 provides a heat transfer path between the first and second principal planes 110 and 120.

The substrate body layer 130 is formed of a Si-based material. The Si-based material can transfer heat at high efficiency and can be as good as that of a conventional ceramic or metal substrate. The substrate body layer formed of the Si-based material may be obtained by appropriately cutting out a piece of a Si wafer that is widely used in a semiconductor manufacturing process, which means that each of the substrates 100A, 100B, 100C, and 100D may be manufactured at a relatively low cost in comparison to a conventional printed circuit board (PCB), an insulated metal substrate (IMS), a pre-molded substrate, or a direct bonded copper (DBC) substrate. Also, because the semiconductor devices 200A and 200B, which are mounted on each of the substrates 100A, 100B, 100C, and 100D, are generally formed of a Si-based material, there is no difference in the thermal expansion coefficients of the substrates 100A, 100B, 100C, and 100D and the semiconductor devices 200A and 200B. As a result, in embodiments of the present invention, a semiconductor device package according to an embodiment of the invention has high durability against repetitive heat cycles that are present during the operation of the semiconductor device package.

As illustrated in FIG. 1A, the first principal plane 110 of the substrate 100A may be defined or provided by an insulation layer. The insulation layer may be a Si oxide film or a Si nitride film, which is formed by performing a conventional semiconductor manufacturing process such as a chemical vapor deposition (CVD) process, a sol-gel process, etc.

Alternatively, as illustrated in FIGS. 1B and 1C, conductive pattern 50a and 50b may be formed on the first principal plane 110 having an insulation surface. The conductive patterns 50a and 50b may be formed by sequentially processes including, for example, a sputtering process that is a film forming process, and a patterning process that is performed using a plasma, as a semiconductor manufacturing process. The conductive patterns 50a and 50b may be formed of copper (Cu), silver (Ag), or an alloy thereof. Because conditions for a metallization process are already established in the semiconductor manufacturing process, and the sputtering and patterning processes are highly precise processes, the conductive patterns 50a and 50b may be easily formed.

As illustrated in FIG. 1B, the conductive patterns 50a may include at least one die attach paddle 51a, upon which the semiconductor devices 200A and 200B are attached, and interconnection pads 52a which are electrically connected to each other by a wire bonding process. As illustrated in FIG. 1C, the conductive patterns 50b may include at least one die attach paddle 51b and contact pads 52b, (such as under-bump metallization (UBM) layers) which are electrically connected to each other by a conductive bump or solder ball bonding process.

According to some embodiments of the present invention, as illustrated in FIG. 1C, the substrate 100C may include a redistribution layer 53 in order to electrically connect at least two of the interconnection pads 52a and contact pads 52b to each other. Although not shown in FIG. 1B, the substrate 100B may also include the redistribution layer 53 in order to electrically connect at least two of the interconnection pads 52a to each other. The redistribution layer 53 may be formed on a surface of the first principal plane 110. Alternatively, in order to be electrically insulated from the die attach paddles 51b, the redistribution layer 53 may be buried in the substrate body layer 130 and an insulation layer (not shown) may be disposed between the die attach paddles 51b and the redistribution layer 53.

According to some embodiments of the present invention, as illustrated in FIG. 1D, in the substrate 100D, a base substrate 10 that functions as a heat sink, may be attached on the second principal plane 120. The base substrate 10 may be formed of aluminum (Al), Cu, or an alloy thereof. In order to increase a surface area for dissipating heat, the base substrate 10 may be machined to have protrusive patterns 10a (e.g., fins).

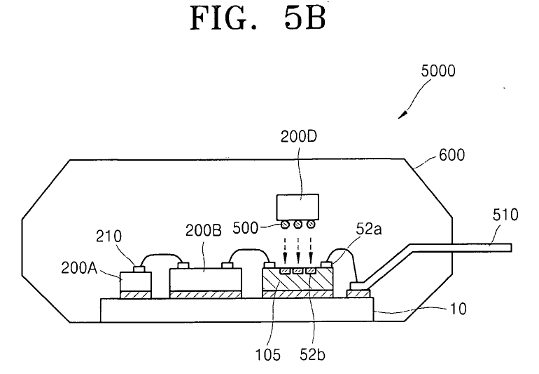

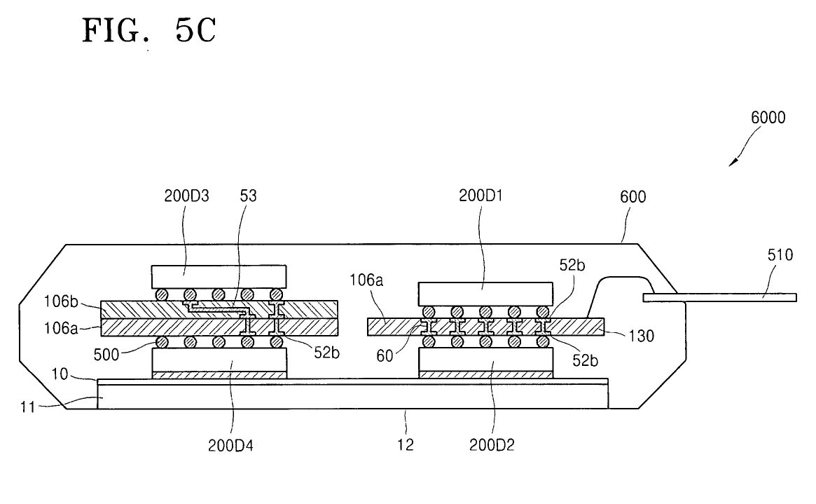

The second principal plane 120 of each of the substrates 100A, 100B, and 100C may be directly exposed outside of a molding member so as to provide a heat dissipation surface. Alternatively, as illustrated in FIG. 1D, if the base substrate 10 is attached on the substrate 100D, a surface of the base substrate 10 may be directly exposed outside the molding member so as to provide a heat dissipation surface. The base substrate 10 will be described in detail later with reference to FIGS. 5A through 5C. In order to improve heat dissipation efficiency, the base substrate 10 may include a surface having a wrinkle structure.

Semiconductor device packages according to various embodiments of the present invention, which include the above substrates 100A, 100B, 100C, and 100D, will now be described.

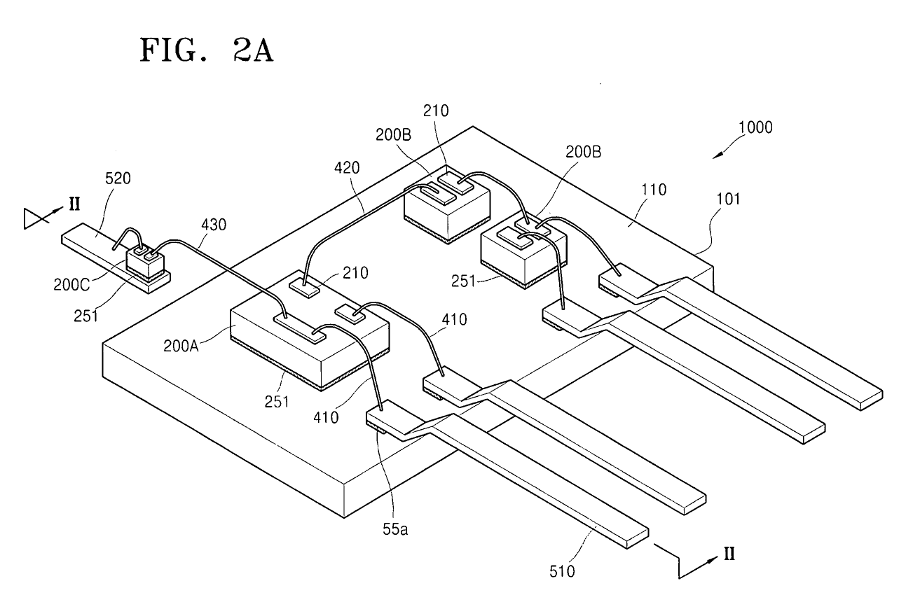

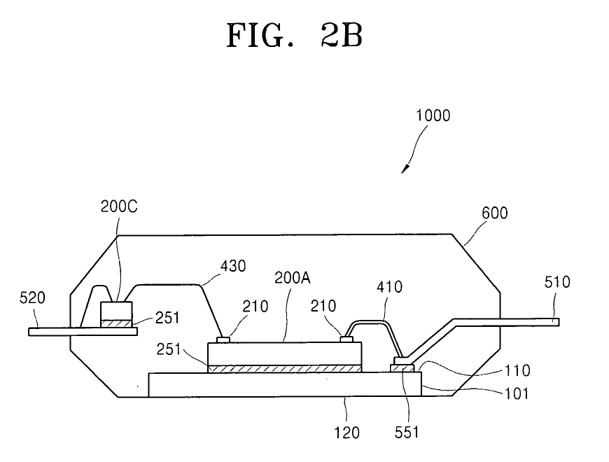

FIG. 2A is a perspective view of a semiconductor device package 1000 according to an embodiment of the present invention. FIG. 2B is a cross-sectional view of the semiconductor device package 1000 which is illustrated in FIG. 2A and is taken along a line II-II. For convenience of explanation, a molding member 600 for protecting internal components thereof is omitted in FIG. 2A. However, the molding member 600 is fully illustrated in FIG. 2B.

Referring to FIGS. 2A and 2B, the semiconductor device package 1000 includes the substrate 101 as a substrate 100A illustrated in FIG. 1A. One or more semiconductor devices 200A and 200B are mounted on a first principal plane 110 of the substrate 101. The semiconductor devices 200A and 200B may be attached on a first principal plane 110 by using a non-conductive adhesive member comprising an elastomer, an epoxy paste and a high temperature tape such as Silicon tape, glass tape and ceramic tape. The semiconductor devices 200A and 200B may be, for example, a power device such as a MOSFET, a bipolar junction transistor (BJT), an insulated gated BJT or a diode for implementing a servo driver, an inverter, a power regulator or a converter device or may be a low-power control device, e.g., an integrated logic chip for controlling the power device. By integrating the power device and the low-power control device for controlling the power device, into a single package, a smart or intelligent power module may be provided. The above-mentioned devices are only examples and the semiconductor device package 1000 is not limited thereto.

A conductive material such as a lead frame (not shown) for providing a plurality of leads 510 may be disposed on the first principal plane 110 of the substrate 101. The lead frame may be attached on the first principal plane 110 of the substrate 101 by using the above-mentioned non-conductive bonding member. Some of the leads 510 may be electrically connected to connection pads 210 of the semiconductor devices 200A and 200B through wires 410. The electrical connection between the semiconductor devices 220A and 200B may be implemented using wires 420.

In some embodiments of the present invention, the semiconductor device package 1000 may further include at least one lead 520 which may be provided by the lead frame (not shown) in order to mount a low-power control device 200C thereon. The low-power control device 200C may be electrically connected to the semiconductor devices 200A and 200B of the substrate 101 through a wire 430.

Although not shown in FIGS. 2A and 2B, in some embodiments of the present invention, by using a lead frame including die attach paddles, the semiconductor devices 200A and 200B may be mounted on the die attach paddles. In this case, the semiconductor devices 200A and 200B may be mounted on the die attach paddles by using a conductive adhesive member such as solder paste or a conductive epoxy. Then, a wiring process is performed, and the molding member 600 is formed by a transfer molding process using a thermosetting resin such as an epoxy mold compound (EMC).

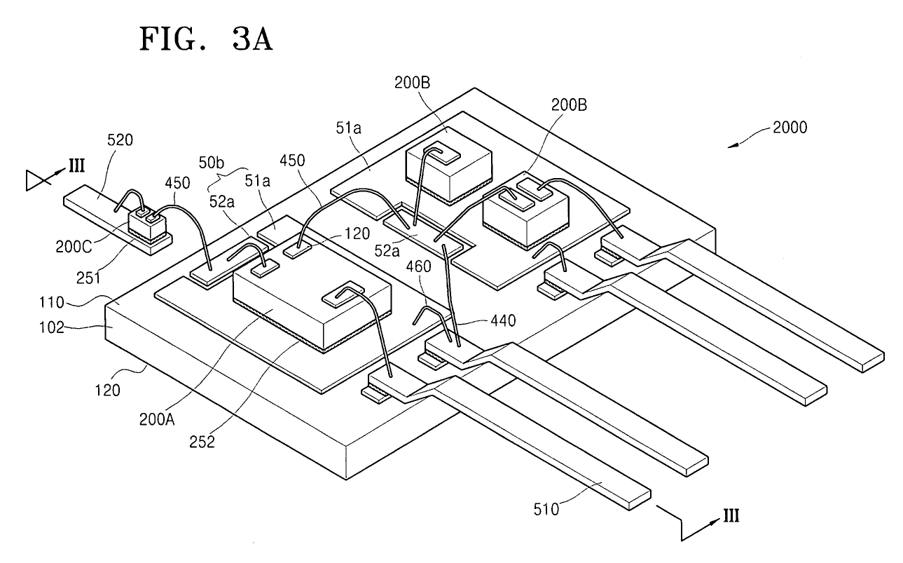

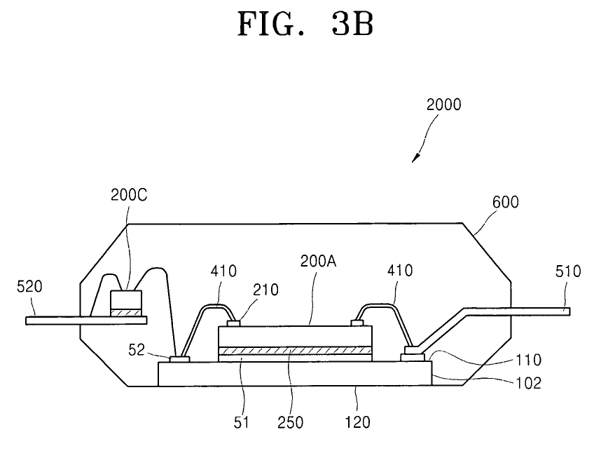

FIG. 3A is a perspective view of a semiconductor device package 2000 according to another embodiment of the present invention. FIG. 3B is a cross-sectional view of the semiconductor device package 2000 which is illustrated in FIG. 3A and is taken along a line III-III.

Referring to FIGS. 3A and 3B, unlike the semiconductor device package 1000 illustrated in FIGS. 2A and 2B, the semiconductor device package 2000 may include the substrate 102 as a substrate 100B illustrated in FIG. 1B. Some of leads 510 may be electrically connected to interconnection pads 52a which are formed on the substrate 100, through a wire 440. Also, semiconductor devices 200A and 200B may be electrically connected to each other through wires 450 by using the interconnection pads 52a as an intermediary. When lower surfaces of the semiconductor devices 200A and 200B are used as electrodes, the semiconductor devices 200A and 200B are attached on die attach paddles 51a using a conductive adhesive member 252 such as a metallic epoxy or solder, and the die attach paddles 51a may be electrically connected to other elements through wires 460.

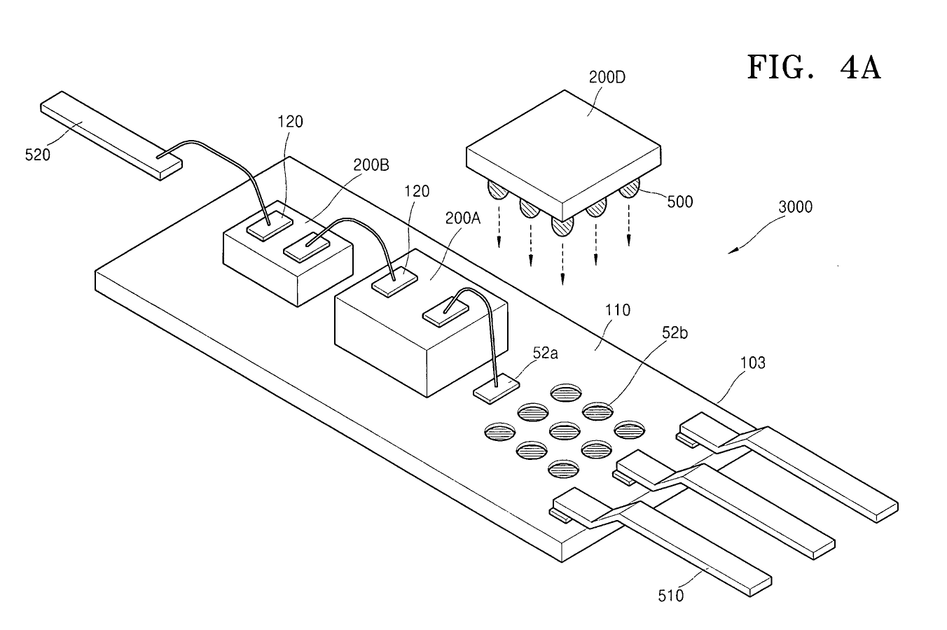

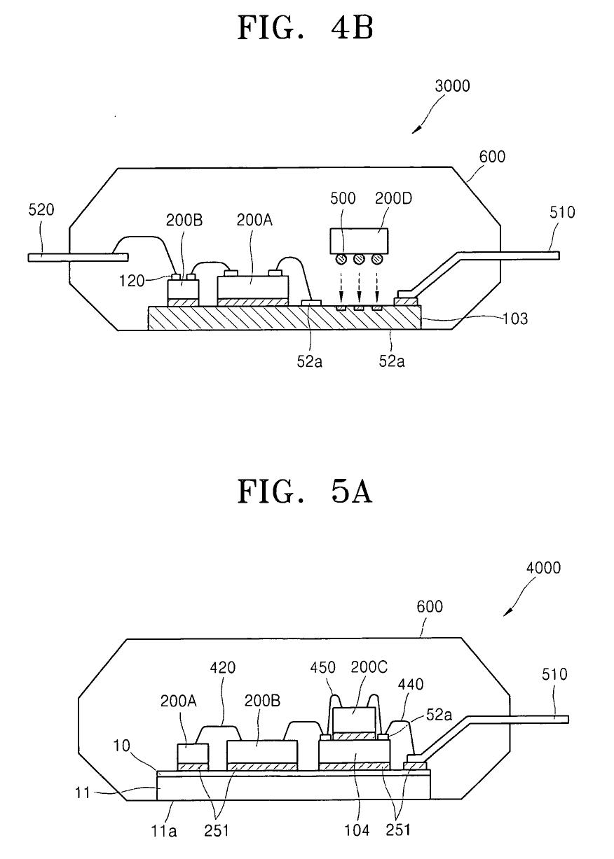

FIG. 4A is a perspective view of a semiconductor device package 3000 according to another embodiment of the present invention. FIG. 4B is a cross-sectional view of the semiconductor device package 3000 which is illustrated in FIG. 4A and is taken along a line IV-IV.

Referring to FIGS. 4A and 4B, unlike the semiconductor device package 2000 illustrated in FIGS. 3A and 3B, the semiconductor device package 3000 may include the substrate 103 as a substrate 100C illustrated in FIG. 1C. Although the substrate 103 includes interconnection pads 52a and contact pads 52b, instead of the die attach paddles 51b which are illustrated in FIG. 1C, the substrate 103 may also include the die attach paddles 51b and semiconductor devices 200A and 200B may be attached on the die attach paddles 51b. In some embodiments of the present invention, at least two of the interconnection pads 52a and the contact pads 52b may be electrically connected to each other by a redistribution layer (not shown).

A semiconductor device 200D is electrically connected to the contact pads 52b which are formed on the substrate 103, by using a conductive connection member 500 such as conductive bumps or solder balls. A well-known flip-chip packaging method may be used as a bonding method of the conductive connection member 500. For example, the conductive connection member 500 is formed by performing bumping and reflow processes on external terminals of the semiconductor device 200D and then the semiconductor device 200D is bonded with the substrate 100 by aligning, heating, and pressing the conductive connection member 500 onto the contact pads 52b of the substrate 103. Alternatively, the conductive connection member 500 may be formed on the contact pads 52b of the substrate 103. Also, the reflow process maybe re-performed or an under fill process may be performed. Unlike the previous embodiments of FIGS. 2A through 3B, according to the current embodiment, a complicated wiring process may be omitted and a thickness of the whole semiconductor device package 3000 may be reduced.

In each of the semiconductor device packages 1000, 2000, and 3000, which are respectively illustrated in FIGS. 2A through 4B, a second principal plane 120 of the substrate 101, 102 and 103 may be exposed outside of a molding member 600 so as to provide a heat dissipation surface. However, a substrate according to other embodiments of the present invention may be encapsulated into a molding member.

FIGS. 5A through 5C are cross-sectional views of semiconductor device packages 4000, 5000, and 6000, respectively, in which a substrate 104, a substrate 105, and substrates 106a and 106b are respectively encapsulated into a molding member 600 and are used as signal substrates, according to various embodiments of the present invention.

Referring to FIGS. 5A and 5B, each of the semiconductor device packages 4000 and 5000 includes a base substrate 10 that is attached on a second principal plane 120 of the substrate 104 or the substrate 105. The base substrate 10 may be attached with the substrate 104 or 105 by using a non-conductive adhesive member 251.

The base substrate 10 may be a conventional PCB, an IMS, a pre-molded substrate, or a DBC substrate. According to some embodiments of the present invention, the substrate 100A illustrated in FIG. 1A or the substrate 100B illustrated in FIG. 1B may be used as the base substrate 10. A heat sink 11 may be attached on a lower surface of the base substrate 10. In this case, a lower surface 12 of the heat sink 11 may be exposed outside the molding member 600.

The substrate 104 or the substrate 105, which is encapsulated into the molding member 600, may function as a signal substrate that is an intermediary for electrically connecting semiconductor devices 200D and/or leads 510. As illustrated in FIG. 5A, a semiconductor device 200C may be electrically connected to a semiconductor device 200B through wires 450 by using interconnection pads 52a which are formed on a first principal plane 110 of the substrate 140, as an intermediary. The semiconductor device 200B may be electrically connected to a semiconductor device 200A directly through a wire 420 without using the interconnection pads 52a as an intermediary. The interconnection pads 52a may be electrically connected to at least one of the leads 510 through a wire 440.

According to another embodiment of the present invention, as illustrated in FIG. 5B, the semiconductor device 200D may be electrically connected to contact pads 52b of the substrate 105 by using a conductive connection member 500. By omitting a wire bonding, a thickness of the semiconductor device package 5000 may be reduced. In this case, the semiconductor device 200D may be a low-power control device that needs a large number of external terminals.

Referring to FIG. 5C, the substrates 106a and 106b may be used to vertically stack semiconductor devices 200D1, 200D2, 200D3, and 200D4. In some embodiments of the present invention, the semiconductor devices 200D1 and 200D2 are respectively stacked on first and second principal planes 110 and 120 of the substrate 106a so as to opposite each other. Contact pads 52b are formed on the first and second principal planes 110 and 120 and the contact pads 52b may be bonded with a conductive connection member 500 so as to be electrically connected to the semiconductor devices 200D1 and 200D2. Lower surfaces of the semiconductor devices 200D2 and 200D4 may be attached with a base substrate 10 by using a conductive or non-conductive adhesive member.

At least one of the contact pads 52b, which are formed on the first and second principal planes 110 and 120 of the substrate 106a, may be electrically connected to each other by via conductors 60 which pierce through a substrate body layer 130. Optionally, in addition to the via conductors 60, the contact pads 52b which are formed on the first and second principal planes 110 and 120 of the substrate 106a may be electrically connected to each other by a redistribution layer 53.

Also, in some embodiments of the present invention, at least two substrates including the substrates 106a and 106b may be stacked on one another. As described above, the semiconductor devices 200D3 and 200D4 are respectively mounted on the principal plane 110 of the substrate 106b and the principal plane 120 of the substrate 106a. In this case, one of the stacked substrates 106a and 106b may include the via conductors 60 and the other one may include the redistribution layer 53. However, the present invention is not limited thereto. Various changes may be made to the configuration of the via conductors 60 and the redistribution layer 53. For example, unlike FIG. 5C, the substrate 106a may include the redistribution layer 53 and the substrate 106b may include the via conductors 60, or each of the substrates 106a and 106b may include the redistribution layer 53 and the via conductors 60.

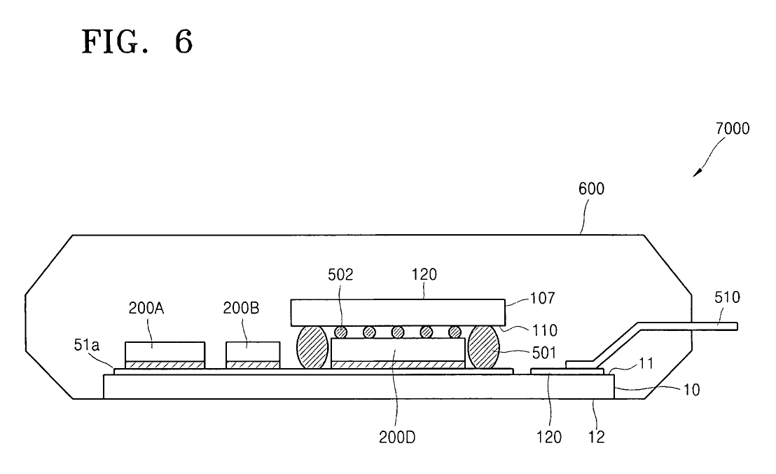

FIG. 6 is a cross-sectional view of a semiconductor device package 7000 according to another embodiment of the present invention.

Referring to FIG. 6, the semiconductor device package 7000 includes a substrate 107 which is encapsulated into a molding member 600 and is used as a signal substrate of a semiconductor device 200D. The semiconductor device 200D is disposed between a first principal plane 110 of the substrate 107 and a first principal plane 11 of a base substrate 10. The substrate 107, the semiconductor device 200D, and the base substrate 10 are electrically connected to each other by using a plurality of conductive connection members 501 and 502. The conductive connection members 502 are bonded with external terminals of the semiconductor device 200D and the conductive connection members 501 are bonded with contact pads (not shown) which may be formed on the first principal plane 11 of the base substrate 10. Heights of the conductive connection members 501 and 502 may be determined using the distances from the first principal plane 110 of the substrate 107 to the semiconductor device 200D, and to the first principal plane 11 of the base substrate 10.

Conventionally, a control device for controlling a power device needs a large number of signal input/output terminals as well as a power terminal, as external terminals. It is complicated to electrically connect the external terminals of the control device by performing a wire bonding process and thus a small and light package cannot be easily manufactured. However, the substrate 107 according to the embodiments of the present invention can be manufactured by performing a semiconductor manufacturing process in which micro patterning is available, and thus a small and light package can be manufactured without short problems which occur in the wire bonding process. In particular, when semiconductor devices 200A and 200B are power devices and the semiconductor device 200D is a control device for controlling the power devices, it is the most advantageous to apply the substrate 107 for the semiconductor device 200D. Empirically, in comparison to a case when the wire bonding process is applied to the semiconductor device 200D, the volume of the semiconductor device package 7000 is reduced by 20% or more.

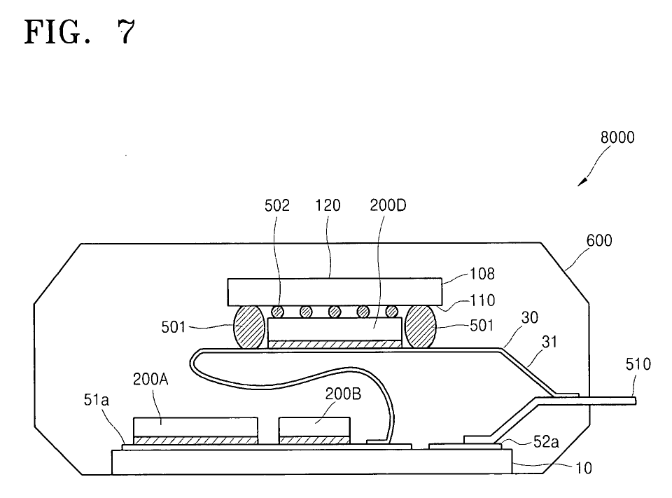

FIG. 7 is a cross-sectional view of a semiconductor device package 8000 according to another embodiment of the present invention.

Referring to FIG. 7, the semiconductor device package 8000 includes a substrate 108 which is encapsulated into a molding member 600 and is used as a signal substrate of a semiconductor device 200D. The semiconductor device 200D may be disposed between a first principal plane 110 of the substrate 108 and a first principal plane 31 of a flexible PCB (FPCB) 30. The substrate 108, the semiconductor device 200D, and the FPCB 30 may be electrically connected to each other by using a plurality of conductive connection members 501 and 502. The conductive connection members 502 may be bonded with external terminals of the semiconductor device 200D and the conductive connection members 501 may be bonded with connection pads (not shown) which are formed on the first principal plane 31 of the FPCB 30. Heights of the conductive connection members 501 and 502 may be determined in consideration of distances from the first principal plane 110 of the substrate 108 to the semiconductor device 200D, and to the first principal plane 31 of the FPCB 30.

When the semiconductor devices 200A and 200B are power devices and the semiconductor device 200D is a control device such as an 1C for controlling the semiconductor devices 200A and 200B, by mounting the semiconductor device 200D on the FPCB 30 that is separated from the base substrate 10, a heat transfer from the semiconductor devices 200A and 200B to the semiconductor device 200D may be reduced and thus operation errors of the semiconductor device 200D may be reduced. As in the semiconductor device package 7000 illustrated in FIG. 6, if the semiconductor device 200D is a control device, the substrate 108 according to the current embodiment of the present invention functions as a signal substrate of the control device to replace the complicated wire bonding process. Also, the substrate 108 may be micro patterned and thus the semiconductor device package 8000 may be minimized without problems of shorts. In comparison to a case when the wire bonding process is performed on the control device, the volume of the semiconductor device package 8000 is reduced by 30% or more.

As described above, according to the embodiments of the present invention, by using a substrate formed of a silicon (Si)-based material such as a Si wafer that is widely used in a semiconductor manufacturing process, as a base substrate, a semiconductor device package has an excellent heat dissipation characteristic and a thermal resistance, and may be manufactured at a relatively low cost, may be provided.

Furthermore, according to the embodiments of the present invention, by using a substrate which is formed of a Si-based material and is micro patterned, as a signal substrate, a small and light semiconductor device package may be manufactured by minimizing or substituting a wire bonding process.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor device package comprising:
a first substrate which comprises first and second principal planes which are opposite each other, and a substrate body layer disposed between the first and second principal planes, the substrate body layer being formed of a silicon (Si)-based material; and
at least one first semiconductor device which is mounted on the first principal plane.

2. The semiconductor device package of claim 1, wherein the first substrate is a base substrate and at least a portion of the second principal plane of the first substrate is exposed outside a molding member.

3. The semiconductor device package of claim 1, further comprising a base substrate which is attached on the second principal plane of the first substrate, the base substrate comprising a bottom surface exposed outside of a molding member.

4. The semiconductor device package of claim 1, wherein the first substrate further comprises at least one first conductive pattern which is formed on the first principal plane and is electrically connected to the first semiconductor device.

5. The semiconductor device package of claim 4, wherein the at least one first conductive pattern comprises at least one first contact pad.

6. The semiconductor device package of claim 4, wherein the at least one first conductive pattern comprises at least one die attach paddle upon which the first semiconductor device is mounted.

7. The semiconductor device package of claim 4, where the at least one first conductive pattern comprises at least two conductive patterns, and wherein the first substrate further comprises a redistribution layer for electrically connecting the at least two of the first conductive patterns to each other.

8. The semiconductor device package of claim 5, wherein the at least one first contact pad is electrically connected to an external terminal of the first semiconductor device, by using a conductive connection member.

9. The semiconductor device package of claim 8, wherein the conductive connection member comprise a conductive bump or a solder ball.

10. The semiconductor device package of claim 8, wherein the first semiconductor device is mounted on the first principal plane in a flip-chip configuration.

11. The semiconductor device package of claim 6, wherein the first semiconductor device is bonded on the at least one die attach paddle by using adhesive members, and
wherein the semiconductor device package further comprises a wire bond, wherein the at least one first contact pad is electrically connected to an external terminal of the first semiconductor device, using the wire bond.

12. The semiconductor device package of claim 4, further comprising a second semiconductor device which is mounted on the second principal plane of the first substrate.

13. The semiconductor device package of claim 12, wherein the first substrate further comprises a plurality of second conductive patterns which are formed on the second principal plane, and
wherein the plurality of second conductive patterns is electrically connected to the second semiconductor device.

14. The semiconductor device package of claim 13, wherein the at least one first conductive pattern and the plurality of second conductive patterns are electrically connected to each other by a via conductor which pierces through the substrate body layer of the first substrate.

15. The semiconductor device package of claim 12, wherein the first substrate further comprises a redistribution layer which electrically connects at least one of the first conductive patterns and at least one of the second conductive patterns, to each other.

16. The semiconductor device package of claim 13, wherein the first and second semiconductor devices are electrically connected to at least one of the first conductive patterns and at least one of the second conductive patterns, respectively, by using conductive connection members.

17. The semiconductor device package of claim 16, wherein the conductive connection members are conductive bumps or solder balls.

18. The semiconductor device package of claim 13, wherein the first substrate is formed of at least two substrate body layers which are stacked on one another.

19. The semiconductor device package of claim 18, wherein at least one of the substrate body layers comprises a redistribution layer, and
wherein at least another one of the substrate body layers comprises a via conductor.

20. The semiconductor device package of claim 1, wherein the first semiconductor device is a power device or a low-power control device for controlling the power device.

21. A semiconductor device package comprising:
a first substrate comprising a first principal plane on which a plurality of first conductive patterns are formed, a second principal plane which is opposite the first principal plane, and a substrate body layer disposed between the first and second principal planes, the substrate body layer being formed of a silicon (Si)-based material;
a second substrate comprising a first principal plane on which a plurality of second conductive patterns are formed, and a second principal plane which is opposite the first principal plane; and
a semiconductor device disposed between the first principal plane of the first substrate and the first principal plane of the second substrate, the semiconductor device being electrically connected to at least one of the first conductive patterns and at least one of the second conductive patterns, by using a plurality of conductive connection members.

22. The semiconductor device package of claim 21, wherein the conductive connection members are conductive bumps or solder balls.

23. The semiconductor device package of claim 21, wherein the conductive connection members comprise:
a first conductive connection member which has a first height and bonds at least one of the first conductive patterns of the first substrate with an external terminal of the semiconductor device; and
a second conductive connection member which has a second height and bonds at least another portion of the first conductive patterns of the first substrate with at least a portion of the second conductive patterns of the second substrate.

24. The semiconductor device package of claim 21, wherein the second substrate is a flexible printed circuit board (FPCB).

25. The semiconductor device package of claim 21, wherein the second substrate is a printed circuit board (PCB), an insulated metal substrate (IMS), a pre-molded substrate, or a direct bonded copper (DBC) substrate.

26. The semiconductor device package of claim 21, wherein the semiconductor device is a power device or a low-power control device for controlling the power device.

27. The semiconductor device package of claim 21, wherein the second substrate is a base substrate and the base substrate comprises at least a portion of a lower surface exposed outside a molding member.

28. The semiconductor device package of claim 21, wherein the second conductive patterns of the second substrate comprises at least one die attach paddle on which the semiconductor device is mounted.

29. The semiconductor device package of claim 21, wherein the first substrate further comprises a redistribution layer for electrically connecting at least two of the first conductive patterns to each other.

30. A method for forming a semiconductor device package, the method comprising:
obtaining a first substrate which comprises first and second principal planes which are opposite each other, and a substrate body layer disposed between the first and second principal planes, the substrate body layer being formed of a silicon (Si)-based material; and
mounting at least one first semiconductor device on the first principal plane.

31. A method for semiconductor device package, the method comprising:
obtaining a first substrate comprising a first principal plane on which a plurality of first conductive patterns are formed, a second principal plane which is opposite the first principal plane, and a substrate body layer disposed between the first and second principal planes, the substrate body layer being formed of a silicon (Si)-based material;
obtaining a second substrate comprising a first principal plane on which a plurality of second conductive patterns are formed, and a second principal plane which is opposite the first principal plane; and
providing a semiconductor device between the first principal plane of the first substrate and the first principal plane of the second substrate, the semiconductor device being electrically connected to at least one of the first conductive patterns and at least one of the second conductive patterns, by using a plurality of conductive connection members.
